(19) United States
(12) Patent Application Publication
(10) Pub. No.: US 2025/0334397 A1
(43) Pub. Date: Oct. 30, 2025

(54) METHOD OF PRODUCING REFERENCE-SPECTRUM LIBRARY FOR USE IN ESTIMATION OF FILM THICKNESS OF WORKPIECE

(71) Applicant: EBARA CORPORATION, Tokyo (JP)

(72) Inventor: Yuki WATANABE, Tokyo (JP)

(21) Appl. No.: 19/186,153

(22) Filed: Apr. 22, 2025

(30) Foreign Application Priority Data
Apr. 26, 2024 (JP) 2024-072826

(51) Int. Cl. G01B 11/06; H01L 21/66; H01L 21/67

(52) U.S. Cl. CPC G01B 11/0625; G01B 11/0683; H01L 21/67092; H01L 21/67253; H01L 22/12; H01L 22/20

(57) ABSTRACT

A method of producing a reference-spectrum library that can improve an accuracy of film thicknesses corresponding to reference spectra is disclosed. The method includes: generating reference spectra of reflected light from the reference workpiece obtained at polishing times during polishing of the reference workpiece; calculating polishing index values indicative of a progress of polishing of the reference workpiece from the reference spectra; determining a polishing-rate line indicative of a relationship between film thickness and polishing time of the reference workpiece from the initial film thickness, the polishing index values, and the final film thickness; determining reference film thicknesses corresponding to the polishing index values based on the polishing-rate line; and producing the reference-spectrum library by associating the reference film thicknesses with the reference spectra, respectively.

### CROSS REFERENCE TO RELATED APPLICATION

This document claims priority to Japanese Patent Application No. 2024-072826 filed Apr. 26, 2024, the entire contents of which are hereby incorporated by reference.

### BACKGROUND

An optical film-thickness measuring device is configured to generate a measurement spectrum of reflected light from a wafer, determine a reference spectrum having a shape that is closest to the measurement spectrum from a reference-spectrum library, and determine a film thickness that has been associated in advance with the determined reference spectrum. FIG. 17 is a diagram illustrating a process of determining a film thickness from a comparison between a measurement spectrum and a plurality of reference spectra. The optical film-thickness measuring device compares the measurement spectrum generated during polishing of a workpiece with the plurality of reference spectra prepared in advance, determines a reference spectrum having a shape that is closest to a shape of the measurement spectrum, and determines a film thickness that has been associated in advance with the determined reference spectrum. The reference spectrum having a shape that is closest to that of the measurement spectrum is a spectrum having the smallest difference in shape between the reference spectrum and the measurement spectrum.

The plurality of reference spectra are obtained in advance by polishing a reference wafer having the same surface structure as a wafer to be polished. Each reference spectrum is associated with a film thickness at a point in time when the reference spectrum is obtained. Specifically, the plurality of reference spectra are obtained when the reference wafer has different film thicknesses, and the plurality of reference spectra correspond to the different film thicknesses. Thus, by identifying a reference spectrum that is closest in shape to the measurement spectrum, a current film thickness of the wafer can be estimated.

An example of a process of acquiring the plurality of reference spectra and corresponding film thicknesses will be described. First, the reference wafer having the same surface structure as that of the wafer to be polished is prepared. The reference wafer is transported to a film-thickness measuring device, and an initial film thickness Tini of the reference wafer is measured by the film-thickness measuring device. Next, the reference wafer is transported to a polishing apparatus, and the reference wafer is polished by the polishing apparatus. During the polishing of the reference wafer, a surface of the reference wafer is irradiated with light, and a spectrum of reflected light from the reference wafer (i.e., a reference spectrum) is generated. The reference spectrum is periodically generated during the polishing of the reference wafer. Thus, during the polishing of the reference wafer, a plurality of reference spectra are acquired as the film thickness decreases. After the polishing of the reference wafer is terminated, the reference wafer is transported to the film-thickness measuring device again, and a film thickness (i.e., a final film thickness Tfin) of the polished reference wafer is measured.

FIG. 18 is a graph showing a relationship between film thickness of the reference wafer and polishing time. When a polishing rate (which may be called a removal rate) of the reference wafer is constant, as shown in FIG. 18, the film thickness decreases linearly with the polishing time from the initial film thickness Tini to the final film thickness Tfin. In other words, the film thickness can be expressed by a linear function including the polishing time as a variable. The polishing rate can be calculated by dividing a difference between the initial film thickness Tini and the final film thickness Tfin by a difference between a polishing timetfin at the final film thickness Tfin and a polishing time tini at the initial film thickness Tini (polishing rate=[Tini−Tfin]/[tfin−tini]).

Times t1, t2, . . . , tn at which the multiple reference spectra are generated are within a range from the polishing time tini to the polishing time tfin. The film thicknesses corresponding to the reference spectra can be calculated from the initial film thickness Tini, the final film thickness Tfin, and the times t1 to tn at which the reference spectra are generated. For example, a film thickness corresponding to a reference spectrum generated at time t2 can be calculated from the following formula.

$$Tini - [ Tini - Tfin ] \cdot [ [ t 2 - tini ] / [ tfin - tini ] ]$$

In this manner, the plurality of reference spectra corresponding to the different film thicknesses are obtained. Each reference spectrum is associated with (or linked to) a corresponding film thickness. By identifying a reference spectrum that is closest in shape to a measurement spectrum during polishing of the wafer, the optical film-thickness measuring device can estimate a current film thickness of the wafer from a film thickness associated with the reference spectrum.

In the conventional film-thickness estimation described above, the polishing rate of the reference wafer is assumed to be constant, as shown in FIG. 18. However, an actual polishing rate of the reference wafer may not be constant, as show n in FIG. 19. Therefore, the film thicknesses corresponding to the reference spectra may differ from actual film thicknesses of the reference wafer, resulting in a decrease in the accuracy of the film thickness estimation of the wafer.

### SUMMARY

Therefore, there is provided a method of producing a reference-spectrum library that can improve an accuracy of a plurality of film thicknesses corresponding to a plurality of reference spectra.

Embodiments, which will be described below, relate to a method of producing a reference-spectrum library for use in estimation of a film thickness of a workpiece, such as a wafer or substrate, and more particularly to a method of producing a reference-spectrum library that includes a plurality of reference spectra that are to be compared to a measurement spectrum of reflected light from the workpiece.

In an embodiment, there is provided a method of producing a reference-spectrum library for use in estimation of a film thickness of a workpiece, comprising: measuring an initial film thickness of a reference workpiece before being polished; polishing the reference workpiece with a polishing apparatus; generating a plurality of reference spectra of reflected light from the reference workpiece obtained at a plurality of polishing times during polishing of the reference workpiece; measuring a final film thickness of the reference workpiece after polishing of the reference workpiece; calculating a plurality of polishing index values indicative of a progress of polishing of the reference workpiece from the plurality of reference spectra; determining a polishing-rate line indicative of a relationship between film thickness and polishing time of the reference workpiece from the initial film thickness, the polishing index values, and the final film thickness; determining a plurality of reference film thicknesses corresponding to the plurality of polishing index values based on the polishing-rate line; and producing the reference-spectrum library by associating the plurality of reference film thicknesses with the plurality of reference spectra, respectively.

In an embodiment, calculating the plurality of polishing index values comprises: calculating a plurality of amounts of change between the plurality of reference spectra, each amount of change being an amount of change between temporally adjacent two of the plurality of reference spectra; and calculating the plurality of polishing index values by accumulating the plurality of amounts of change one by one arranged according to the polishing time of the reference workpiece.

In an embodiment, determining the polishing-rate line comprises: calculating a provisional polishing-rate line from the initial film thickness and the final film thickness, under an assumption that a polishing rate of the reference workpiece is constant; and determining the polishing-rate line by correcting the provisional polishing-rate line based on changes in the plurality of polishing index values over polishing time.

In an embodiment, calculating the plurality of polishing index values comprises: calculating a plurality of provisional film thicknesses of the reference workpiece from the initial film thickness, the final film thickness, and the plurality of polishing times, under an assumption that a polishing rate of the reference workpiece is constant; performing a principal component analysis on each of the plurality of reference spectra to obtain a plurality of principal components including a first principal component to a k-th principal component (k is a natural number equal to or greater than 2) for each of the reference spectra; classifying the plurality of principal components obtained for the plurality of reference spectra into a plurality of groups of the first principal component to the k-th principal component; determining a plurality of correlation coefficients corresponding to the plurality of groups by calculating the plurality of correlation coefficients between the plurality of principal components included in each of the plurality of groups and the plurality of provisional film thicknesses; determining a first group having a largest absolute value of a correlation coefficient and a second group having a second largest absolute value of a correlation coefficient from among the plurality of correlation coefficients; arranging the plurality of principal components included in the first group on a first coordinate axis of a coordinate system; arranging the plurality of principal components included in the second group on a second coordinate axis of the coordinate system; and determining the plurality of polishing index values which area plurality of data points specified by the plurality of principal components on the first coordinate axis and the plurality of principal components on the second coordinate axis.

In an embodiment, there is provided a method of producing a reference-spectrum library for use in estimation of a film thickness of a workpiece, comprising: measuring an initial film thickness of a reference workpiece before being polished; polishing the reference workpiece with a polishing apparatus; generating a plurality of reference spectra of reflected light from the reference workpiece obtained at a plurality of polishing times during polishing of the reference workpiece; measuring an intermediate film thickness of the reference workpiece at least once during polishing of the reference workpiece; measuring a final film thickness of the reference workpiece after polishing of the reference workpiece; determining a polishing-rate line indicating a relationship between film thickness and polishing time of the reference workpiece from the initial film thickness, the intermediate film thickness, and the final film thickness; determining a plurality of reference film thicknesses at the plurality of polishing times from the polishing-rate line; and producing the reference-spectrum library by associating the plurality of reference film thicknesses with the plurality of reference spectra, respectively.

According to the above embodiments, the reference spectrum is generated from the reflected light from the reference workpiece during polishing. Therefore, the polishing index values calculated from the reference spectra reflect the progress of polishing of the reference workpiece. The polishing-rate line determined from the initial film thickness, the polishing index values, and the final film thickness reflects a change in the actual polishing rate of the reference workpiece. Therefore, the accuracy of the reference film thicknesses determined using the polishing-rate line can be improved.

According to the above embodiments, the polishing-rate line is created based on the plurality of measurement values of the film thickness of the reference workpiece. Therefore, the accuracy of the reference film thicknesses determined using the polishing-rate line can be improved.

### BRIEF DESCRIPTION OF THE DRAWINGS

FIG. 1 is a schematic diagram showing an embodiment of a polishing apparatus;

FIG. 2 is a cross-sectional view showing a detailed configuration of an optical film-thickness measuring device;

FIG. 3 is a schematic diagram showing an example of a measurement spectrum generated from light-intensity measurement data;

FIG. 4 is a schematic diagram illustrating an embodiment of a workpiece processing system including a polishing apparatus and a film-thickness measuring apparatus for use in a method of producing a reference-spectrum library;

FIG. 5 is a graph showing adjacent two reference spectra arranged according to the polishing time;

FIG. 6 is a graph showing an amount of change in the reference spectrum calculated per unit time in a polishing time of a reference workpiece;

FIG. 7 is a graph showing a plurality of polishing index values calculated by accumulating a plurality of amounts of change in the reference spectrum one by one;

FIG. 8 is a graph showing an example of a provisional polishing-rate line when a polishing rate of the reference workpiece is assumed to be constant;

FIG. 9 is a diagram illustrating a process of determining a polishing-rate line by correcting the provisional polishing-rate line based on changes in a plurality of polishing index values with polishing time;

FIG. 10 is a flow chart illustrating an embodiment of a method of producing a reference-spectrum library;

FIG. 11 is a diagram showing an example of a plurality of polishing index values identified from a plurality of first principal components and a plurality of second principal components;

FIG. 12 is a diagram illustrating a process of determining the polishing-rate line by correcting the provisional polishing-rate line based on the changes in the plurality of polishing index values with polishing time;

FIG. 13 is a flow chart illustrating an embodiment of a method of producing a reference-spectrum library;

FIG. 14 is a flowchart illustrating the embodiment;

FIG. 15 is a graph showing an example of a polishing-rate line showing a relationship between film thickness of a reference workpiece and polishing time;

FIG. 16 is a flow chart illustrating an embodiment of a method of producing a reference-spectrum library;

FIG. 17 is a diagram illustrating a process of determining a film thickness from a comparison of a measurement spectrum with multiple reference spectra;

FIG. 18 is a graph showing a relationship between film thickness and polishing time of a reference wafer; and

FIG. 19 is a graph showing an example in which a polishing rate of a reference wafer is not constant.

### DESCRIPTION OF EMBODIMENTS

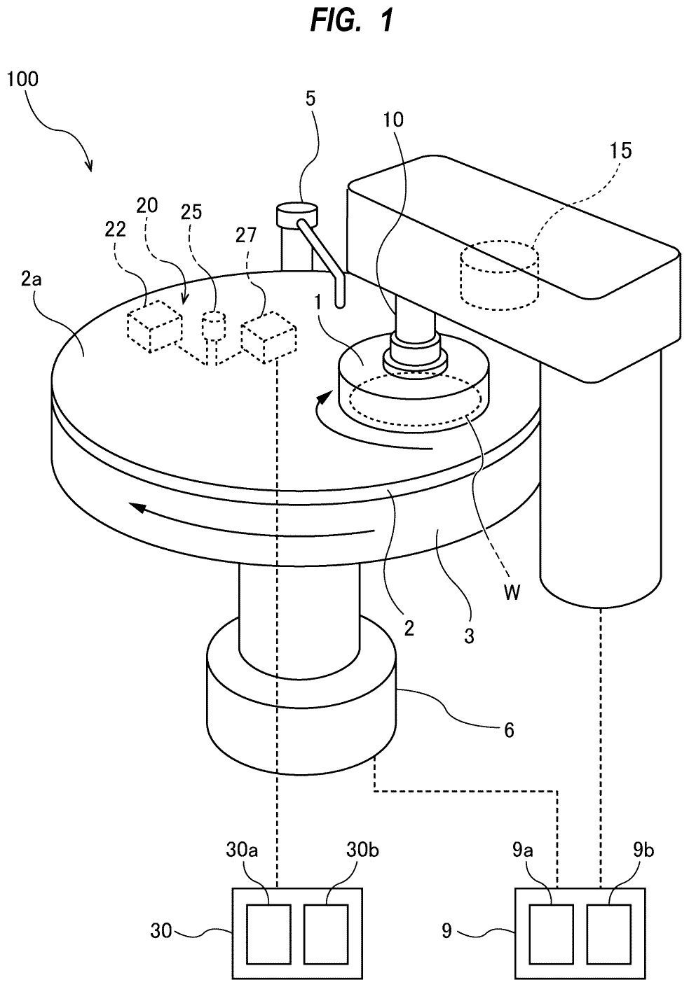

Hereinafter, embodiments will be described with reference to the drawings. FIG. 1 is a schematic diagram showing an embodiment of a polishing apparatus. As shown in FIG. 1, a polishing apparatus 100 includes a polishing table 3 supporting a polishing pad 2, a polishing head 1 configured to press a workpiece W against the polishing pad 2, a table motor 6 configured to rotate the polishing table 3, a polishing-liquid supply nozzle 5 configured to supply a polishing liquid, such as a slurry, onto the polishing pad 2, and an operation controller 9 configured to control operations of the polishing apparatus 100. An upper surface of the polishing pad 2 constitutes a polishing surface 2a for polishing the workpiece W. The workpiece W has a film constituting an interconnect structure on a surface of the workpiece W. Examples of the workpiece W include a wafer, a substrate, an interconnect substrate, a quadrangular substrate, or the like for use in manufacturing of semiconductor devices. In one example, the workpiece W is a product wafer on which a multilayer film is formed.

The polishing head 1 is coupled to ahead shaft 10, which is coupled to a polishing-head rotating device 15. The polishing-head rotating device 15 is configured to rotate the polishing head 1 together with the head shaft 10 in a direction indicated by arrow. Configuration of the polishing-head rotating device 15 is not particularly limited, while in one example, the polishing-head rotating device 15 includes an electric motor, a belt, pulleys, etc. The polishing table 3 is coupled to the table motor 6, which is configured to rotate the polishing table 3 and the polishing pad 2 in a direction indicated by arrow. The polishing head 1, the polishing-head rotating device 15, and the table motor 6 are coupled to the operation controller 9.

The workpiece W is polished as follows. The polishing liquid is supplied from the polishing-liquid supply nozzle 5 to the polishing surface 2a of the polishing pad 2 on the polishing table 3, while the table motor 6 and the polishing-head rotating device 15 rotate the polishing table 3 and the polishing head 1 in the directions shown by the arrows in FIG. 1. While the workpiece W is rotated by the polishing head 1, the workpiece W is pressed against the polishing surface 2a of the polishing pad 2 by the polishing head 1 with the polishing liquid present on the polishing pad 2. The surface of the workpiece W is polished by a chemical action of the polishing liquid and a mechanical action of abrasive grains contained in the polishing liquid and/or the polishing pad 2.

The operation controller 9 includes a memory 9a in which programs are stored, and an arithmetic device 9b configured to execute arithmetic operations according to instructions included in the programs. The operation controller 9 includes at least one computer. The memory 9a includes a main memory, such as a random access memory (RA M), and an auxiliary memory, such as a hard disk drive (HDD) or a solid state drive (SSD). Examples of the arithmetic device 9b include a CPU (Central Processing Unit) and a GPU (Graphics Processing Unit). However, the specific configuration of the operation controller 9 is not limited to these examples.

The polishing apparatus 100 includes an optical film-thickness measuring device 20 configured to measure a film thickness of the workpiece W. The optical film-thickness measuring device 20 includes alight source 22 configured to emit light, an optical sensor head 25 configured to irradiate the workpiece W with the light from the light source 22 and receives reflected light from the workpiece W, a spectrometer 27 coupled to the optical sensor head 25, and a processing system 30 configured to determine the film thickness of the workpiece W based on a spectrum of the reflected light from the workpiece W. The optical sensor head 25 is disposed within the polishing table 3 and rotates together with the polishing table 3.

The processing system 30 includes a memory 30a in which programs are stored, and an arithmetic device 30b configured to execute arithmetic operations according to instructions included in the programs. The processing system 30 is composed of at least one computer. The memory 30a includes a main memory, such as a random access memory (RA M), and an auxiliary memory, such as a hard disk drive (HDD) or a solid state drive (SSD). Examples of the arithmetic device 30b include a CPU (Central Processing Unit) and a GPU (Graphics Processing Unit). However, the specific configuration of the processing system 30 is not limited to these examples.

Each of the operation controller 9 and the processing system 30 may be composed of a plurality of computers. For example, each of the operation controller 9 and the processing system 30 may be composed of a combination of an edge server and a cloud server. In one embodiment, the operation controller 9 and the processing system 30 may be composed of a single computer.

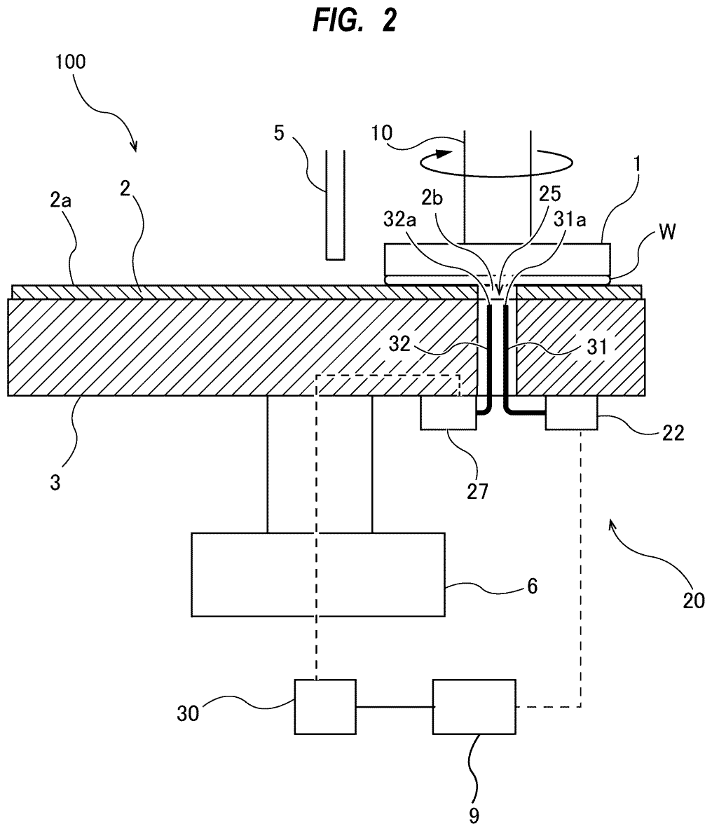

FIG. 2 is a cross-sectional view showing a detailed configuration of the optical film-thickness measuring device 20. The optical film-thickness measuring device 20 includes a light-emitting optical fiber cable 31 coupled to the light source 22 and a light-receiving optical fiber cable 32 coupled to the spectrometer 27. A distal end 31a of the light-emitting optical fiber cable 31 and a distal end 32a of the light-receiving optical fiber cable 32 constitute the optical sensor head 25. Specifically, the light-emitting optical fiber cable 31 directs the light emitted by the light source 22 to the workpiece W on the polishing pad 2, and the light-receiving optical fiber cable 32 receives the reflected light from the workpiece W and transmits the reflected light to the spectrometer 27.

The spectrometer 27 is coupled to the processing system 30. The light-emitting optical fiber cable 31, the light-receiving optical fiber cable 32, the light source 22, and the spectrometer 27 are attached to the polishing table 3 and rotate together with the polishing table 3 and the polishing pad 2. The optical sensor head 25, which is composed of the distal end 31a of the light-emitting optical fiber cable 31 and the distal end 32a of the light-receiving optical fiber cable 32, is disposed facing the surface of the workpiece W on the polishing pad 2.

The optical sensor head 25 is arranged such that the optical sensor head 25 sweeps across the surface of the workpiece W on the polishing pad 2 each time the polishing table 3 and polishing pad 2 make one rotation. The polishing pad 2 has a through-hole 2b located above the optical sensor head 25. The optical sensor head 25 irradiates the light onto the workpiece W through the through-hole 2b each time the polishing table 3 makes one rotation, and receives the reflected light from the workpiece W through the through-hole 2b.

In one embodiment, a flow of pure water may be formed in the through-hole 2b of the polishing pad 2 so as to prevent the polishing liquid and polishing debris from contacting the optical sensor head 25. The light is directed from the optical sensor head 25 through the pure water to the workpiece W, and the reflected light from the workpiece W is received by the optical sensor head 25 through the pure water. In another embodiment, a transparent window (not shown) may be fitted in the through-hole 2b of the polishing pad 2. The transparent window is made of a material (e.g., transparent resin) that allows the light to pass therethrough. In this case, the light is directed from the optical sensor head 25 through the transparent window to the workpiece W, and the reflected light from the workpiece W is received by the optical sensor head 25 through the transparent window.

The light source 22 may be a flash light source that repeatedly emits the light at short time intervals. An example of the light source 22 is a xenon flash lamp. The light source 22 is electrically coupled to the operation controller 9, and emits the light upon receiving a trigger signal sent from the operation controller 9. M ore specifically, when the optical sensor head 25 is moving across the surface of the workpiece W on the polishing pad 2, the light source 22 receives multiple trigger signals and emits the light multiple times. Therefore, each time the polishing table 3 makes one rotation, the light is directed to a plurality of film-thickness measurement points on the workpiece W including a central point of the workpiece W.

The light emitted by the light source 22 is transmitted to the optical sensor head 25. Specifically, the light is transmitted to the optical sensor head 25 through the light-emitting optical fiber cable 31 and is emitted from the optical sensor head 25. The light travels through the through-hole 2b of the polishing pad 2 and is incident on the workpiece W on the polishing pad 2. The reflected light from the workpiece W travels through the through-hole 2b of the polishing pad 2 again and is received by the optical sensor head 25. The reflected light from the workpiece W is transmitted to the spectrometer 27 through the light-receiving optical fiber cable 32.

The spectrometer 27 is configured to resolve the reflected light according to wavelength and measure intensity of the reflected light at each of wavelengths of the reflected light over a predetermined wavelength range. Specifically, the spectrometer 27 resolves the reflected light from the workpiece W according to wavelength and measures the intensity of the reflected light at each of the wavelengths over a predetermined wavelength range to generate light-intensity measurement data. The intensity of the reflected light at each wavelength may be expressed as a relative value, such as reflectance or relative reflectance. The light-intensity measurement data is sent to the processing system 30.

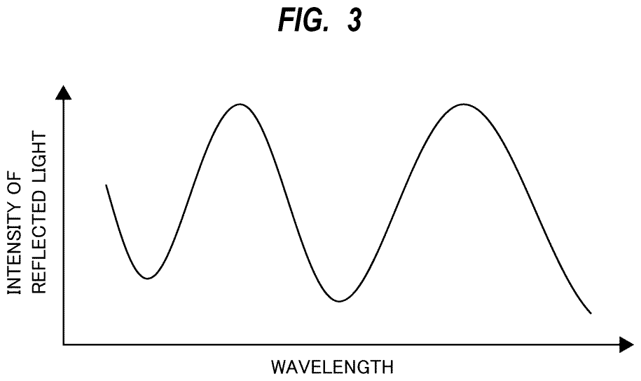

The processing system 30 generates a spectrum of the reflected light as shown in FIG. 3 from the light-intensity measurement data. In the following descriptions, the spectrum of the reflected light from the workpiece W is referred to as measurement spectrum. The measurement spectrum of the reflected light from the workpiece W includes information on the film thickness of the workpiece W. In other words, the measurement spectrum of the reflected light varies depending on the film thickness of the workpiece W. The processing system 30 is configured to determine the film thickness of the workpiece W based on the measurement spectrum of the reflected light. More specifically, the processing system 30 determines, from a reference-spectrum library, a reference spectrum having a shape closest to a shape of the measurement spectrum of the reflected light, and determines a film thickness associated with the determined reference spectrum. The reference-spectrum library is produced in advance before polishing of the workpiece W, and is stored in the memory 30a of the processing system 30.

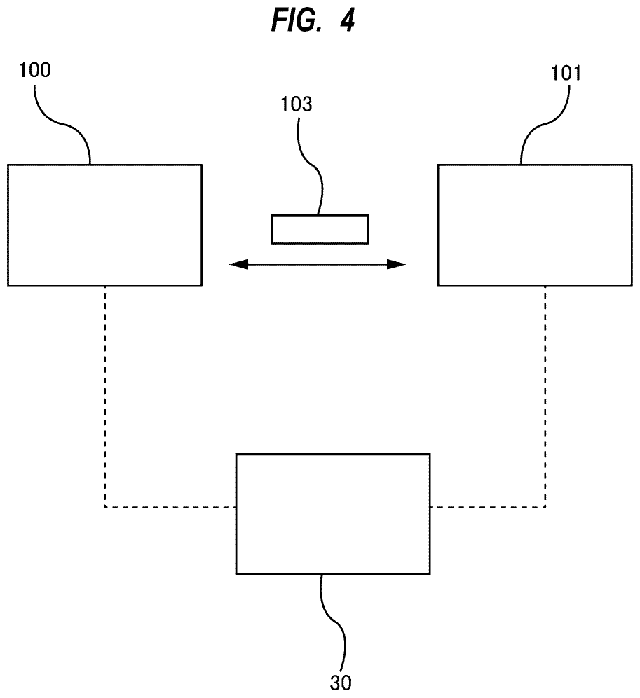

An embodiment of the method of producing the reference-spectrum library will be described below. FIG. 4 is a schematic diagram showing an embodiment of a workpiece processing system including the polishing apparatus 100 and a film-thickness measuring apparatus 101 which are used in the method of producing the reference-spectrum library.

First, a reference workpiece having the same surface structure as a surface structure of the workpiece W is prepared. M ore specifically, the reference workpiece has an exposed surface made of the same material as that of the workpiece W and has the same layer structure as that of the workpiece W. Next, the reference workpiece is transported by a transport device 103 to the film-thickness measuring apparatus 101, and the film-thickness measuring apparatus 101 measures an initial film thickness, which is a film thickness of the reference workpiece before being polished.

The film-thickness measuring apparatus 101 irradiates the reference workpiece in a stationary state with light, generates a spectrum of reflected light from the reference workpiece, and analyzes the spectrum to determine a film thickness of the reference workpiece. The basic principle of film-thickness measuring configuration of the film-thickness measuring apparatus 101 is the same as that of the optical film-thickness measuring device 20, but differs from the optical film-thickness measuring device 20 in that the film thickness of the reference workpiece in a stationary state is measured. The measured value of the initial film thickness is transmitted from the film-thickness measuring apparatus 101 to the processing system 30.

After the measurement of the initial film thickness, the reference workpiece is transported by the transport device 103 to the polishing apparatus 100, and is polished by the polishing apparatus 100. The polishing of the reference workpiece is performed in the same manner as the polishing of the workpiece W. Specifically, the table motor 6 and the polishing-head rotating device 15 rotate the polishing table 3 and the polishing head 1 in the directions indicated by the arrows in FIG. 1, while the polishing liquid is supplied from the polishing-liquid supply nozzle 5 to the polishing surface 2a of the polishing pad 2 on the polishing table 3. While the reference workpiece is rotated by the polishing head 1, the reference workpiece is pressed against the polishing surface 2a of the polishing pad 2 by the polishing head 1 with the polishing liquid present on the polishing pad 2, so that the surface of the reference workpiece is polished.

During polishing of the reference workpiece, the optical sensor head 25 irradiates the reference workpiece with the light, and a spectrum of the reflected light from the reference workpiece is generated, as well as polishing of the workpiece W. In the following description, the spectrum of the reflected light from the reference workpiece is referred to as reference spectrum. Each time the polishing table 3 makes one rotation, the optical sensor head 25 directs the light onto a plurality of film-thickness measurement points, including the central point, on the reference workpiece. Each time the polishing table 3 makes one rotation, the processing system 30 generates the reference spectrum from the light-intensity measurement data generated by the spectrometer 27.

In this manner, a plurality of reference spectra corresponding to a plurality of polishing times are generated during polishing of the reference workpiece as the film thickness of the reference workpiece decreases. After polishing of the reference workpiece, the reference workpiece is transported by the transport device 103 to the film-thickness measuring apparatus 101. A final film thickness, which is a film thickness of the reference workpiece after being polished, is measured by the film-thickness measuring apparatus 101. The measured value of the final film thickness is transmitted from the film-thickness measuring apparatus 101 to the processing system 30.

The processing system 30 calculates a plurality of polishing index values from the plurality of reference spectra. The plurality of polishing index values indicate the progress of polishing of the reference workpiece. M ore specifically, the processing system 30 calculates a plurality of amounts of change between the plurality of reference spectra, and calculates the plurality of polishing index values by accumulating the plurality of amounts of change one by one, which are arranged according to the polishing time of the reference workpiece. Each of the plurality of amounts of change between the plurality of reference spectra is an amount of change in adjacent two reference spectra among the plurality of reference spectra arranged according to polishing time.

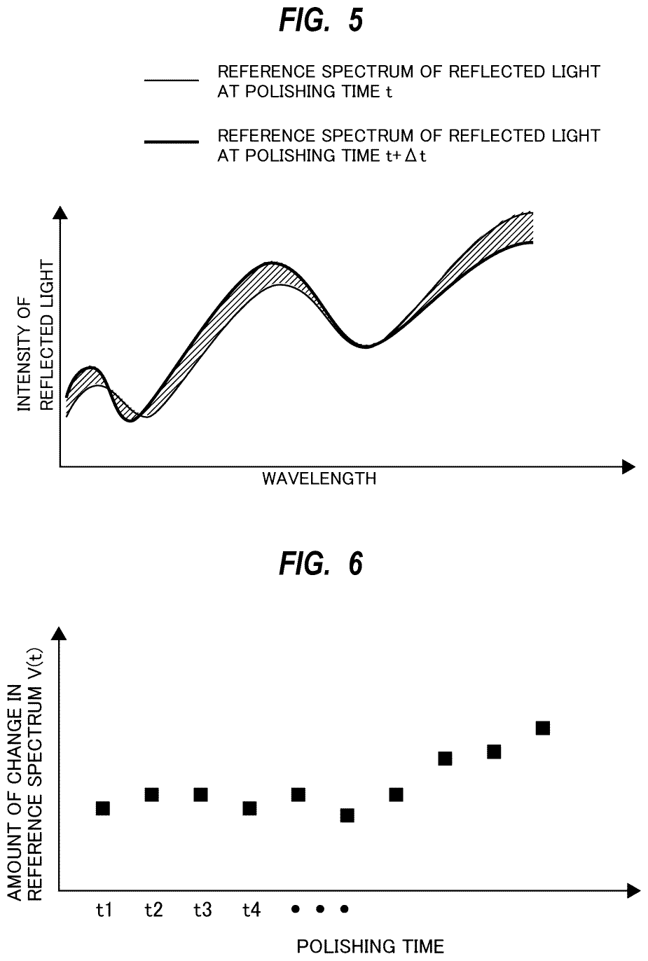

FIG. 5 is a graph showing adjacent two reference spectra arranged according to the polishing time, i.e., temporally adjacent two reference spectra. In FIG. 5, a vertical axis represents the intensity of the reflected light from the reference workpiece, and a horizontal axis represents the wavelength of the reflected light. FIG. 5 shows a reference spectrum of the reflected light at a polishing time t, and a reference spectrum of the reflected light at a polishing time t+Δt. Time Δt is a predetermined unit time. The adjacent two reference spectra arranged according to time (or temporally adjacent two reference spectra) are the reference spectrum of the reflected light at the certain polishing time t and the reference spectrum of the reflected light at the polishing time t+Δt after unit time Δt.

In this embodiment, the reference spectrum is generated every time the polishing table 3 makes one rotation, and therefore, the unit time Δt is a time for the polishing table 3 to make one rotation. In one embodiment, the unit time Δt may be a time for the polishing table 3 to make p rotations (p is a natural number).

Because the reference spectrum is generated from the reflected light from the reference workpiece being polished, the reference spectrum changes gradually as the film thickness decreases (i.e., with the polishing time). Thus, shapes of the multiple reference spectra generated from the reflected light at different polishing times during polishing of the reference workpiece are slightly different. In addition, these reference spectra reflect a change in an actual polishing rate of the reference workpiece.

The amount of change between the two temporally adjacent reference spectra corresponds to a hatched area in FIG. 5. In other words, the amount of change between the two temporally adjacent reference spectra is an amount of change in the reference spectra per unit time Δt. In one embodiment, the amount of change V(t) between the two temporally adjacent reference spectra can be calculated by the following formula (1).

$$V ( t ) = Δλ \cdot {\sum }_{λ = λ 1}^{λ 2} \vert R ( λ , t + Δ t ) - R ( λ , t ) \vert \qquad ( 1 )$$

where, Δλ represents a wavelength increment, λ1 represents a lower limit of the wavelength range of the reference spectrum, 2 represents an upper limit of the wavelength range of the reference spectrum, R(λ, t+Δt) represents an intensity of the reflected light from the reference workpiece at wavelength λ and time t+Δt, and R(λ, t) represents an intensity of the reflected light from the reference workpiece at wavelength λ and time t.

In this embodiment, the reference spectrum is generated each time the polishing table 3 makes one rotation. Therefore, the amount of change between the two temporally adjacent reference spectra is an amount of change in the reference spectra per rotation of the polishing table 3. In one embodiment, the amount of change between the two temporally adjacent reference spectra may be an amount of change in the reference spectra per p rotations (p is a natural number) of the polishing table 3.

The amount of change V(t) in the reference spectrum represented by the above formula (1) is calculated for each unit time Δt. FIG. 6 is a graph showing the amount of change V(t) in the reference spectrum calculated for each unit time within the polishing time of the reference workpiece. In FIG. 6, a vertical axis represents the amount of change V(t) in the reference spectrum, and a horizontal axis represents the polishing time of the reference workpiece. As shown in FIG. 6, a plurality of amounts of change V(t) in the reference spectrum corresponding to a plurality of different polishing times during the polishing of the reference workpiece are obtained.

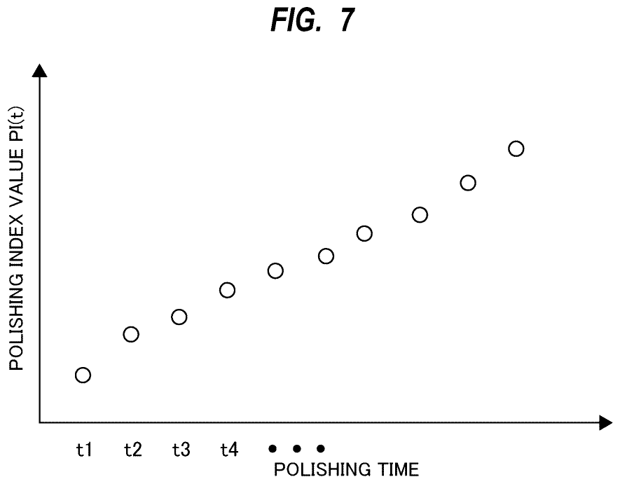

The processing system 30 calculates a plurality of polishing index values, as shown in FIG. 7, by accumulating the plurality of amounts of change V(t) one by one that are arranged according to the polishing time of the reference workpiece. In FIG. 7, a vertical axis represents polishing index value PI(t), and a horizontal axis represents the polishing time of the reference workpiece. The polishing index value PI(t1) at a polishing time t1 is the amount of change V (t1) at the polishing time t. The processing system 30 calculates a polishing index value PI (t2) at a polishing time t2 by adding the amount of change V (t2) at the polishing time t2 to the amount of change V (t1) at the polishing time t1, and calculates a polishing index value PI(t3) at a polishing time t3 by adding the amount of change V (t3) at the polishing time t3 to the polishing index value PI(t2) at the polishing time t2. The processing system 30 calculates the plurality of polishing index values PI(t) by repeating the same calculation. A scan be seen from FIG. 7, the plurality of amounts of change V(t) are accumulated (or integrated) one by one per unit time, so that the polishing index value PI(t) gradually increases with the polishing time.

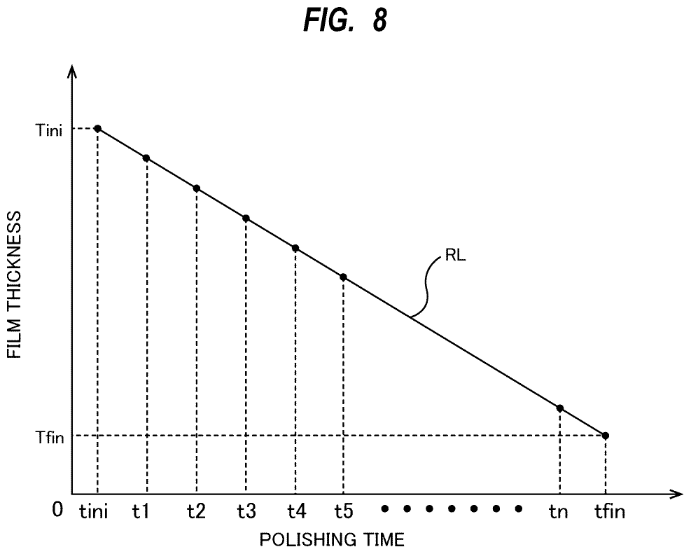

The processing system 30 calculates a provisional polishing-rate line from an initial film thickness, a final film thickness, and two polishing times corresponding to these film thicknesses, under assumption that a polishing rate of the reference workpiece is constant. Specifically, as shown in FIG. 8, the processing system 30 calculates a provisional polishing-rate line RL from an initial film thickness Tini (which is a film thickness before polishing of the reference workpiece), a polishing time tini at the initial film thickness Tini (i.e., a polishing start time of the reference workpiece), a final film thickness Tfin (which is a film thickness after polishing of the reference workpiece), and a polishing time tfin at the final film thickness Tfin (i.e., a polishing end time of the reference workpiece). This provisional polishing-rate line R L decreases at a constant rate (linearly) with the polishing time.

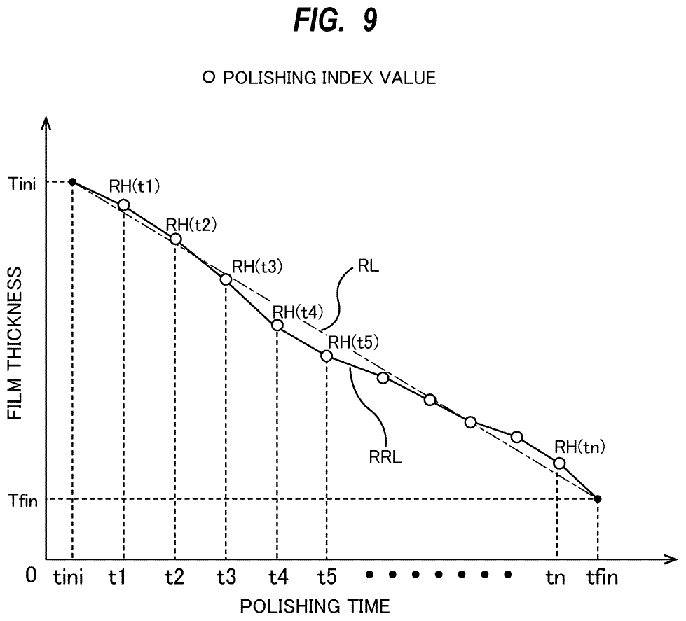

Next, as shown in FIG. 9, the processing system 30 determines a polishing-rate line RRL by correcting the provisional polishing-rate line RL based on changes in the plurality of polishing index values PI(t) over the polishing time shown in FIG. 7. In one embodiment, the processing system 30 converts the plurality of polishing index values PI(t) that increase over the polishing time shown in FIG. 7 into a plurality of polishing index values that decrease over the polishing time, and further applies a process, such as scaling, to the plurality of converted polishing index values, and corrects the provisional polishing-rate line RL so as to pass through the plurality of processed polishing index values, thereby determining the polishing-rate line RRL. In another embodiment, the processing system 30 calculates an approximation curve of the plurality of polishing index values after the scaling process, and replaces sections from time t1 to tn of the provisional polishing-rate line RL with the approximation curve, thereby correcting the provisional polishing-rate line RL to determine the polishing-rate line RRL. However, as long as the polishing-rate line RRL can reflect the changes in the plurality of polishing index values PI(t) shown in FIG. 7 over the polishing time, the method of determining the polishing-rate line RRL is not limited to these embodiments.

The processing system 30 determines a plurality of reference film thicknesses corresponding to the plurality of polishing index values based on the polishing-rate line RRL. Specifically, the processing system 30 determines, from the polishing-rate line RRL, a plurality of reference film thicknesses RH(t1), RH(t2), RH(t3), . . . , RH (tn) at a plurality of polishing times t1, t2, t3, . . . , tn corresponding to the plurality of polishing index values. Furthermore, the processing system 30 associates the plurality of reference film thicknesses with a plurality of reference spectra generated from the reflected light from the reference workpiece when being polished. M ore specifically, the processing system 30 associates the plurality of reference film thicknesses RH(t1), RH(t2), RH(t3), . . . , RH (tn) corresponding to the plurality of polishing times t1, t2, t3, . . . , tn with the plurality of reference spectra generated from the reflected light at the plurality of polishing times t1, t2, t3, . . . , tn, respectively. The plurality of reference spectra and the plurality of corresponding reference film thicknesses thus obtained are added to the reference-spectrum library. The reference-spectrum library is stored in the memory 30a of the processing system 30.

The reference spectrum is generated from the reflected light from the reference workpiece during polishing of the reference workpiece. Thus, the plurality of polishing index values calculated from the reference spectra reflect the progress of polishing of the reference workpiece. The polishing-rate line determined from the initial film thickness, the plurality of polishing index values, and the final film thickness reflects the change in the actual polishing rate of the reference workpiece. Thus, using the polishing-rate linescan improve the accuracy of the plurality of determined reference film thicknesses.

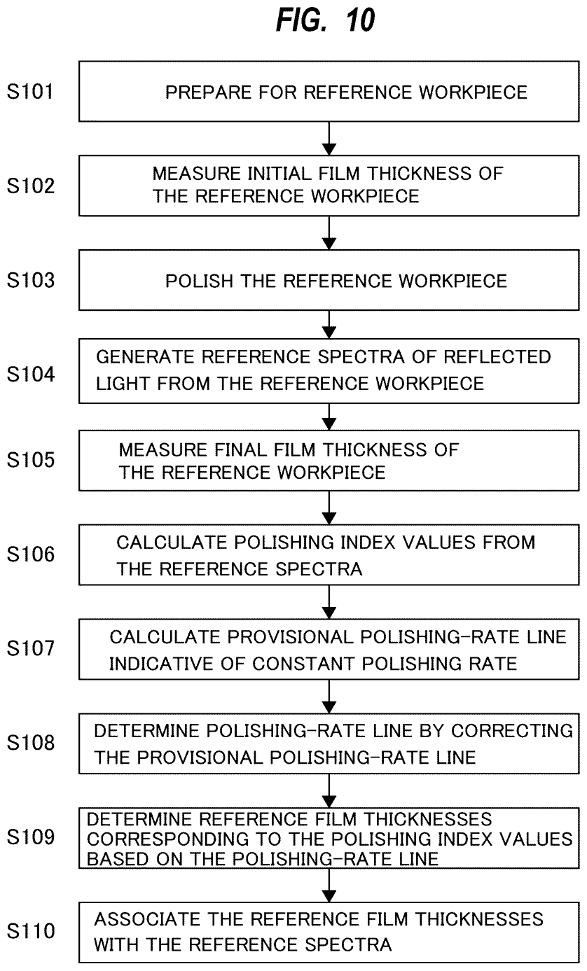

FIG. 10 is a flow chart illustrating one embodiment of the method of producing the reference-spectrum library.

In step S101, the reference workpiece having the same surface structure as the workpiece W is prepared. M ore specifically, the reference workpiece has an exposed surface made of the same material as that of the workpiece W and has the same layer structure.

In step S102, the film-thickness measuring apparatus 101 measures the initial film thickness, which is a film thickness of the reference workpiece before being polished.

In step S103, the reference workpiece is chemically mechanically polished by the polishing apparatus 100.

In step S104, the reference workpiece is irradiated with the light at different polishing times during polishing of the reference workpiece, and the processing system 30 generates the plurality of reference spectra of the reflected light from the reference workpiece.

In step S105, after the reference workpiece is polished, the final film thickness, which is a film thickness of the polished reference workpiece, is measured by the film-thickness measuring apparatus 101.

In step S106, the processing system 30 calculates the plurality of polishing index values indicating the progress of polishing of the reference workpiece from the plurality of reference spectra. In one embodiment, the processing system 30 calculates the plurality of amounts of change between the plurality of reference spectra (see FIG. 6), and calculates the plurality of polishing index values by accumulating the plurality of amounts of change one by one arranged according to the polishing time of the reference workpiece (see FIG. 7).

In step S107, the processing system 30 calculates the provisional polishing-rate line based on the initial film thickness and the final film thickness, under an assumption that the polishing rate of the reference workpiece is constant (see FIG. 8).

In step S108, the processing system 30 determines (creates) the polishing-rate line RRL by correcting the provisional polishing-rate line RL based on the plurality of polishing index values that vary with the polishing time (see FIG. 9). The polishing-rate line RRL corresponds to the provisional polishing-rate line R L that has been corrected based on the plurality of polishing index values.

In step S109, the processing system 30 determines the plurality of reference film thicknesses RH(t1), RH(t2), RH (3), . . . , RH (tn) corresponding to the plurality of polishing index values based on the polishing-rate line RRL.

In step S110, the processing system 30 associates the plurality of reference film thicknesses with the plurality of reference spectra, respectively. The plurality of reference spectra and the plurality of corresponding reference film thicknesses are added to the reference-spectrum library.

Next, another embodiment of a method of producing a reference-spectrum library will be described. Operations of this embodiment that will not be particularly described are the same as those of the embodiments described with reference to FIGS. 1 to 10, and the duplicated descriptions will be omitted. In this embodiment, the measuring of the initial film thickness of the reference workpiece, the polishing of the reference workpiece, the generation of the plurality of reference spectra of the reflected light from the reference workpiece at different polishing times, and the measuring of the final film thickness of the reference workpiece are performed in the same manner as in the embodiments described above.

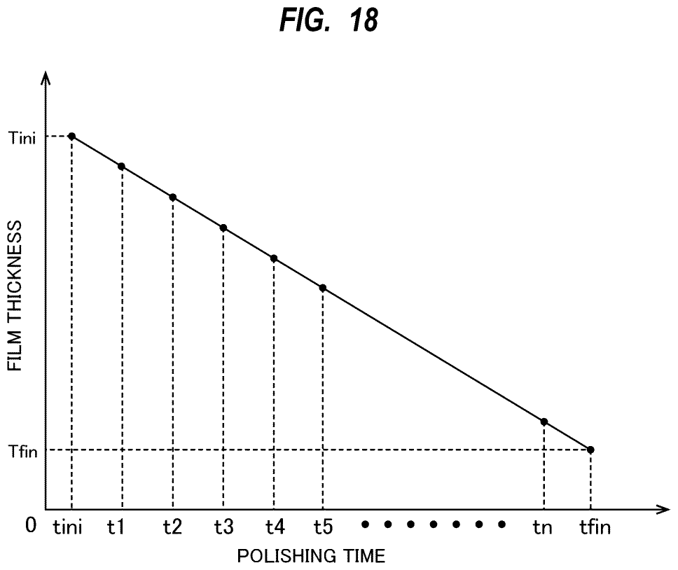

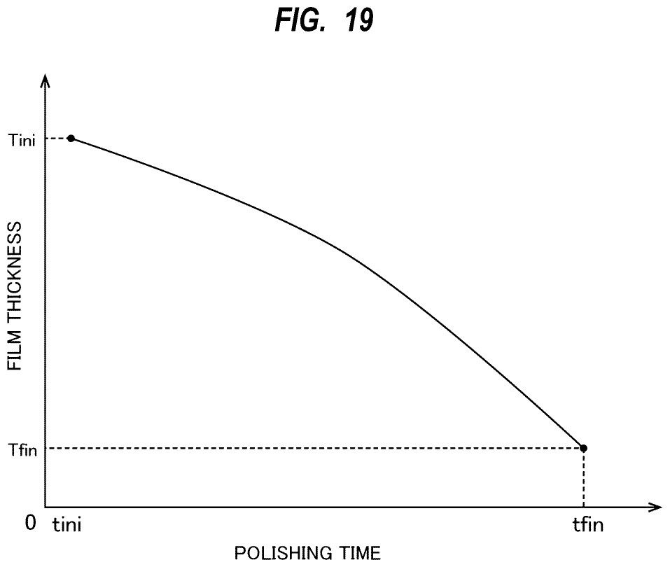

The processing system 30 calculates a provisional polishing-rate line from the initial film thickness and the final film thickness under the assumption that the polishing rate of the reference workpiece is constant. The calculation of the provisional polishing-rate line is performed in the same manner as in the embodiment described with reference to FIG. 8. The processing system 30 calculates a plurality of provisional film thicknesses of the reference workpiece from the provisional polishing-rate line and a plurality of polishing times corresponding to the plurality of reference spectra under the assumption that the polishing rate of the reference workpiece is constant. The plurality of provisional film thicknesses can be calculated according to the method described with reference to FIG. 18. These provisional film thicknesses decrease linearly with the polishing time.

The processing system 30 performs principal component analysis on each of the plurality of reference spectra to obtain a plurality of principal components including a first principal component Z₁ to a k-th principal component Zₖ (k is a natural number equal to or greater than 2) for each reference spectrum. M ore specifically, the processing system 30 performs the principal component analysis on a data set (or dataset) including multiple intensities of the reflected light at multiple wavelengths of each reference spectrum. As described with reference to FIG. 3, each reference spectrum indicates the relationship between intensity and wavelength of the reflected light, and is composed of multiple wavelengths and corresponding multiple intensities of the reflected light. The data set of each reference spectrum includes data on the multiple intensities of that reference spectrum.

In an example described below, the processing system 30 performs the principal component analysis on each reference spectrum to calculate a first principal component Z₁, a second principal component Z₂, a third principal component Z₃, and a fourth principal component Z₄. However, calculation of the first principal component Z₁ to the k-th principal component Zₖ is not limited to the following example, as long as k is a natural number equal to or greater than 2.

Examples of calculating the first principal component Z₁ to the fourth principal component Z₄ are as follows:

$$First principal component {Z}_{1} = {w}_{11} {X}_{1} + {w}_{12} {X}_{2} + {w}_{12} {X}_{3} + …$$

$$Second principal component {Z}_{2} = {w}_{21} {X}_{1} + {w}_{22} {X}_{2} + {w}_{22} {X}_{3} + …$$

$$Third principal component {Z}_{3} = {w}_{31} {X}_{1} + {w}_{32} {X}_{2} + {w}_{32} {X}_{3} + …$$

$$Fourth principal component {Z}_{4} = {w}_{41} {X}_{1} + {w}_{42} {X}_{2} + {w}_{4} {X}_{3} + …$$

where, Xₘ (m is a natural number) represents an intensity of the reflected light at a wavelength λₘ of the reference spectrum, w₁ₘ is a weight coefficient for the intensity Xₘ used in calculating the first principal component Z₁, w₂ₘ is a weight coefficient for the intensity Xₘ used in calculating the second principal component Z₂, w₃ₘ is a weight coefficient for the intensity Xₘ used in calculating the third principal component Z₃, and w₄ₘ is a weight coefficient for the intensity Xₘ used in calculating the fourth principal component Z₄.

In this manner, the first principal component Z₁, the second principal component Z₂, the third principal component Z₃, and the fourth principal component Z₄ are calculated for each reference spectrum. Thus, a plurality of first principal components Z₁, a plurality of second principal components Z₂, a plurality of third principal components Z₃, and a plurality of fourth principal components Z₄ are calculated for the plurality of reference spectra. Because the plurality of reference spectra are generated from the reflected light from the reference workpiece when being polished, the plurality of reference spectra correspond to the plurality of provisional film thicknesses of the reference workpiece.

The processing system 30 classifies the plurality of principal components acquired for the plurality of reference spectra into a plurality of groups of the first principal component Z₁ to the k-th principal component Zₖ. In the above example, the principal components acquired for the reference spectra are classified into four groups: a group G1 of the first principal component Z₁, a group G2 of the second principal component Z₂, a group G3 of the third principal component Z₃, and a group G4 of the fourth principal component Z₄. The group G1 includes the first principal components Z₁ acquired for the plurality of reference spectra, the group G2 includes the second principal components Z₂ acquired for the plurality of reference spectra, the group G3 includes the third principal components Z₃ acquired for the plurality of reference spectra, and the group G4 includes the fourth principal components Z₄ acquired for the plurality of reference spectra.

The processing system 30 determines a plurality of correlation coefficients corresponding to the plurality of groups by calculating the correlation coefficients between the plurality of principal components included in each of the plurality of groups and the plurality of corresponding provisional film thicknesses. Each correlation coefficient is an index representing a strength of correlation between the plurality of principal components belonging to each group and the plurality of corresponding provisional film thicknesses. The larger the correlation coefficient, the stronger the correlation between the principal components and the provisional film thicknesses. The correlation coefficient is calculated according to a known method.

The processing system 30 determines the group with the largest absolute value of the correlation coefficient, and further determines the group with the second largest absolute value of the correlation coefficient among the plurality of correlation coefficients calculated for the plurality of groups. For example, if the correlation coefficient of the group G1 is 0.91, the correlation coefficient of the group G2 is −0.89, the correlation coefficient of the group G3 is −0.32, and the correlation coefficient of the group G4 is −0.05, the group with the largest absolute value of the correlation coefficient is the group G1, and the group with the second largest absolute value of the correlation coefficient is the group G2.

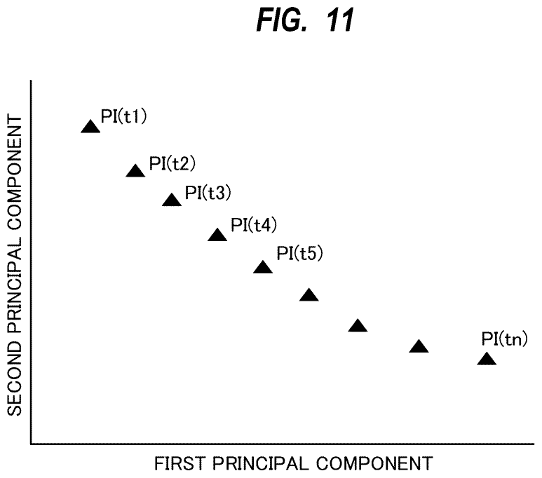

As shown in FIG. 11, the processing system 30 arranges the plurality of first principal components included in the group G1 having the largest absolute value of the correlation coefficient on a first coordinate axis of a coordinate system, and arranges the plurality of second principal components included in the group G2 having the second largest absolute value of the correlation coefficient on a second coordinate axis of the coordinate system. The coordinate system of the embodiment shown in FIG. 11 is an orthogonal coordinate system having the first coordinate axis and the second coordinate axis. The processing system 30 determines a plurality of polishing index values PI(t) which area plurality of data points specified from the plurality of first principal components on the first coordinate axis and the plurality of second principal components on the second coordinate axis.

The plurality of polishing index values PI(t) on the coordinate system are determined from the plurality of first principal components and the plurality of second principal components, which are calculated from the plurality of reference spectra of the reflected light from the reference workpiece. Therefore, the plurality of polishing index values PI(t) on the coordinate system correspond to the plurality of polishing times t1, t2, t3, . . . , tn during polishing of the reference workpiece. In the embodiment shown in FIG. 11, the plurality of polishing index values PI(t) on the coordinate system decrease with the polishing time of the reference workpiece.

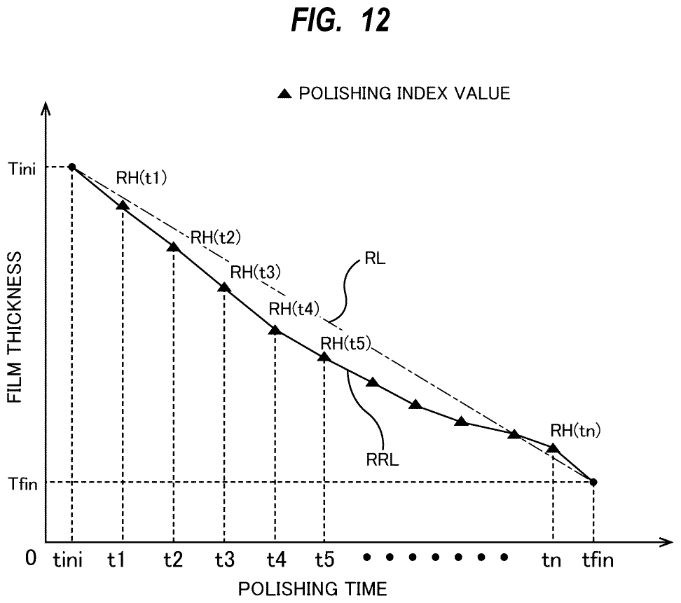

The processing system 30 determines the polishing-rate line by correcting the provisional polishing-rate line, which has been used for the calculation of the provisional film thicknesses of the reference workpiece, based on changes in the plurality of polishing index values PI(t) over the polishing time shown in FIG. 11. In one embodiment, as shown in FIG. 12, the processing system 30 determines the polishing-rate line RRL by applying a process, such as scaling, to the plurality of polishing index values PI(t) and correcting the provisional polishing-rate line RL so as to pass through the plurality of polishing index values that has been subjected to the process. In another embodiment, the processing system 30 calculates an approximation curve for the plurality of polishing index values after the scaling process is applied, and replaces the section from time t1 to tn of the provisional polishing-rate line RL with the approximation curve, thereby correcting the provisional polishing-rate line RL to determine the polishing-rate line RRL. However, as long as the polishing-rate line RRL reflects the changes in the plurality of polishing index values PI(t) over the polishing time shown in FIG. 11, the method of determining the polishing-rate line RRL is not limited to these embodiments.

The processing system 30 determines a plurality of reference film thicknesses corresponding to the plurality of polishing index values based on the polishing-rate line RRL. Specifically, the processing system 30 determines, from the polishing-rate line RRL, a plurality of reference film thicknesses RH(t1), RH(t2), RH(t3), . . . RH(tn) at the plurality of polishing times t1, t2, t3, . . . , tn corresponding to the plurality of polishing index values. Furthermore, the processing system 30 associates the plurality of reference film thicknesses with the plurality of reference spectra generated from the reflected light from the reference workpiece when being polished. M ore specifically, the processing system 30 associates the plurality of reference film thicknesses RH(t1), RH(t2), RH(t3), . . . RH (tn) corresponding to the plurality of polishing times t1, t2, t3, . . . , tn with the plurality of reference spectra generated from the reflected light at the plurality of polishing times t1, t2, t3, . . . , tn, respectively. The plurality of reference spectra and the plurality of corresponding reference film thicknesses thus obtained are added to the reference-spectrum library. The reference-spectrum library is stored in the memory 30a of the processing system 30.

The reference spectrum is generated from the reflected light from the reference workpiece during polishing. Thus, the polishing index values calculated from the reference spectra reflect the progress of polishing of the reference workpiece. The polishing-rate line determined from the initial film thickness, the polishing index values, and the final film thickness reflects the change in the actual polishing rate of the reference workpiece. Thus, using the polishing-rate line can improve the accuracy of the determined reference film thicknesses.

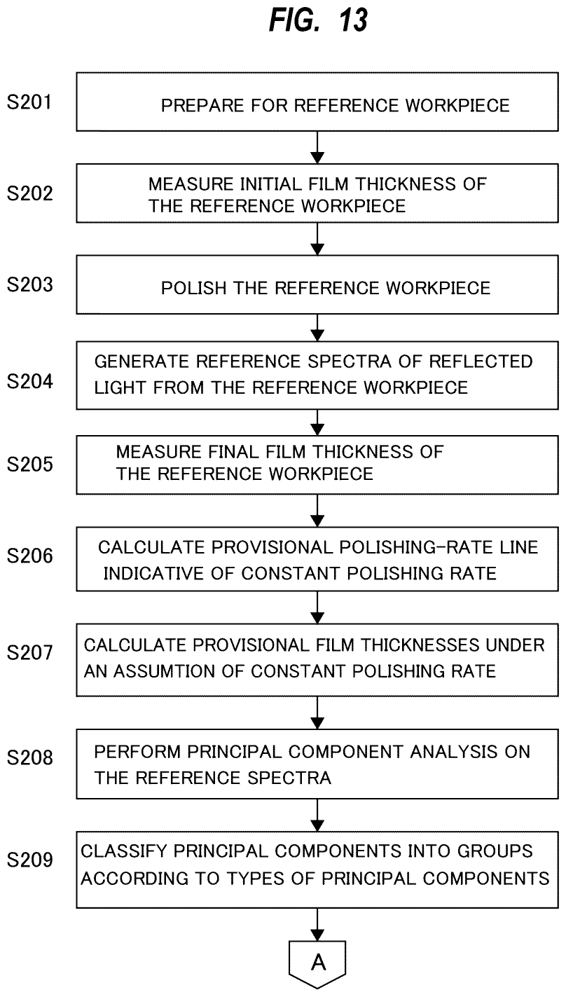

FIG. 13 is a flow chart illustrating one embodiment of the method of producing the reference-spectrum library.

Steps S201 to S205 are the same as the steps S101 to S105 shown in FIG. 11, and duplicated descriptions thereof will be omitted.

In step S206, the processing system 30 calculates the provisional polishing-rate line from the initial film thickness and the final film thickness, under the assumption that the polishing rate of the reference workpiece is constant.

In step S207, the processing system 30 calculates the plurality of provisional film thicknesses of the reference workpiece from the provisional polishing-rate line and the plurality of polishing times corresponding to the plurality of reference spectra, under the assumption that the polishing rate of the reference workpiece is constant.

In step S208, the processing system 30 performs the principal component analysis on each of the plurality of reference spectra to obtain the plurality of principal components including the first principal component Z₁ to the k-th principal component Zₖ (k is a natural number greater than or equal to 2) for each reference spectrum.

In step S209, the processing system 30 classifies the plurality of principal components obtained for the plurality of reference spectra into the plurality of groups of the first principal component Z₁ to the k-th principal component Zₖ.

In step S210, the processing system 30 determines the plurality of correlation coefficients corresponding to the plurality of groups by calculating the correlation coefficients between the plurality of principal components included in each of the plurality of groups and the plurality of corresponding provisional film thicknesses.

In step S211, the processing system 30 determines a group having the largest absolute value of the correlation coefficient and a group having the second largest absolute value of the correlation coefficient from among the plurality of correlation coefficients calculated for the plurality of groups.

In step S212, the processing system 30 arranges the plurality of principal components included in the group having the largest absolute value of the correlation coefficient on the first coordinate axis of the coordinate system, and arranges the plurality of principal components included in the group having the second largest absolute value of the correlation coefficient on the second coordinate axis of the coordinate system.

In step S213, the processing system 30 determines the plurality of polishing index values PI(t), which are a plurality of data points specified from the plurality of principal components on the first coordinate axis and the plurality of principal components on the second coordinate axis (see FIG. 11).

In step S214, the processing system 30 determines (creates) the polishing-rate line RRL by correcting the provisional polishing rate RL, which has been used for calculating the provisional film thickness of the reference workpiece, based on the changes in the plurality of polishing index values PI(t) over the polishing time (see FIG. 12). The polishing-rate line RRL corresponds to the provisional polishing-rate line RL corrected based on the plurality of polishing index values PI(t).

In step S215, the processing system 30 determines, based on the polishing-rate line RRL, the plurality of reference film thicknesses RH(t1), RH(t2), RH(t3), . . . , RH (tn) corresponding to the plurality of polishing index values PI(t).

In step S216, the processing system 30 associates the plurality of reference film thicknesses with the plurality of reference spectra, respectively. The plurality of reference spectra and the plurality of corresponding reference film thicknesses are added to the reference-spectrum library.

Next, still another embodiment of a method of producing a reference-spectrum library will be described. Operations of this embodiment which will not be particularly described are the same as those of the embodiments described with reference to FIGS. 1 to 11, and repetitive descriptions thereof will be omitted. In this embodiment, the polishing index value is not calculated. Instead, in this embodiment, an intermediate film thickness of the reference workpiece is measured at least once during polishing of the reference workpiece. In the embodiment described below, the intermediate film thickness of the reference workpiece is measured multiple times during polishing of the reference workpiece.

The measuring of the initial film thickness of the reference workpiece, the polishing of the reference workpiece, the generation of the plurality of reference spectra of the reflected light from the reference workpiece at different polishing times, and the measuring of the final film thickness of the reference workpiece are performed in the same manner as in the previously described embodiments. The intermediate film thicknesses of the reference workpiece are film thicknesses of the reference workpiece during polishing. The measuring of the intermediate film thicknesses is performed after the measuring of the initial film thickness and before the measuring of the final film thickness.

The initial film thickness and the final film thickness are measured by film-thickness measuring apparatus 101 shown in FIG. 4. The intermediate film thicknesses are measured by film-thickness measuring apparatus 101 shown in FIG. 4 or optical film-thickness measuring device 20 shown in FIG. 2. When the film-thickness measuring apparatus 101 is used to measure the intermediate film thicknesses, polishing of the reference workpiece by the polishing apparatus 100 is temporarily stopped, and the reference workpiece is transported to film-thickness measuring apparatus 101 by the transport device 103, and the intermediate film thicknesses of the reference workpiece are measured by the film-thickness measuring apparatus 101. When the optical film-thickness measuring device 20 is used to measure the intermediate film thicknesses, the intermediate film thicknesses of the reference workpiece are measured by the optical film-thickness measuring device 20 while the reference workpiece is being polished by the polishing apparatus 100.

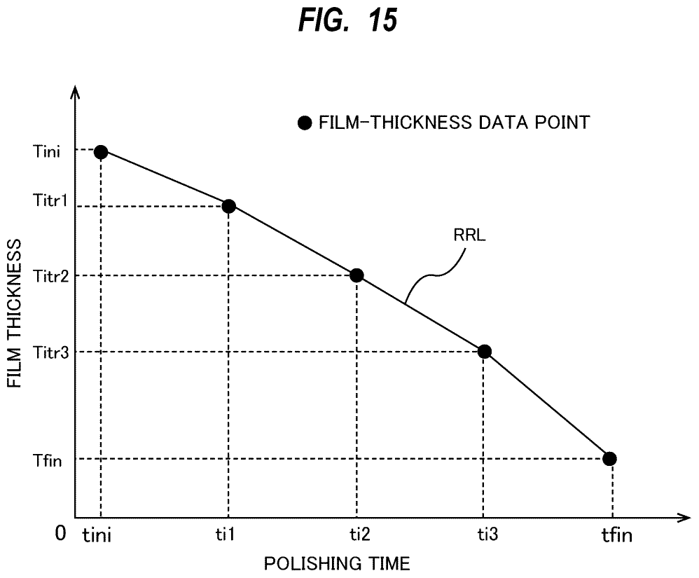

The processing system 30 determines a polishing-rate line showing a relationship between the film thickness of the reference workpiece and the polishing time, from the initial film thickness, the intermediate film thicknesses, and the final film thickness. FIG. 15 is a graph showing an example of the polishing-rate line showing the relationship between the film thickness of the reference workpiece and the polishing time. In FIG. 15, a vertical axis represents the film thickness of the reference workpiece, and a horizontal axis represents the polishing time of the reference workpiece. In the embodiment shown in FIG. 15, three intermediate film thicknesses Titr1, Titr2, and Titr3 are measured by the film-thickness measuring apparatus 101 or the optical film-thickness measuring device 20 after the polishing of the reference workpiece is started and before the polishing of the reference workpiece is terminated. Polishing times ti1, ti2, and ti3 shown in FIG. 15 correspond to the intermediate film thicknesses Titr1, Titr2, and Titr3, respectively.

The processing system 30 determines (creates) a polishing-rate line RRL specified from the initial film thickness Tini, the intermediate film thicknesses Titr1, Titr2, Titr3, the final film thickness Tfin, and the polishing times tini, ti1, ti2, ti3, tfin corresponding to these film thicknesses. In one embodiment, the processing system 30 determines the polishing-rate line RRL passing through film-thickness data points specified from the initial film thickness Tini, the intermediate film thicknesses Titr1, Titr2, Titr3, the final film thickness Tfin, and the corresponding multiple polishing times tini, ti1, ti2, ti3, tfin. In another embodiment, the processing system 30 may determine the polishing-rate line RRL that is an approximation curve of film-thickness data points specified from the initial film thickness Tini, the intermediate film thicknesses Titr1, Titr2, Titr3, the final film thickness Tfin, and the corresponding multiple polishing times tini, ti1, ti2, ti3, tfin.

The processing system 30 determines, from the polishing-rate line RRL, a plurality of reference film thicknesses at a plurality of polishing times corresponding to a plurality of reference spectra of the reflected light from the reference workpiece being polished. The plurality of reference film thicknesses can be determined in the same manner as the embodiment described with reference to FIG. 9. Furthermore, the processing system 30 associates the plurality of reference film thicknesses with the plurality of reference spectra. The plurality of reference spectra and the corresponding plurality of reference film thicknesses thus obtained are added to the reference-spectrum library. The reference-spectrum library is stored in the memory 30a of the processing system 30.

According to this embodiment, the polishing-rate line RRL is created based on the multiple measurements of the film thickness of the reference workpiece, which can improve the accuracy of the multiple reference film thicknesses determined using the polishing-rate line RRL.

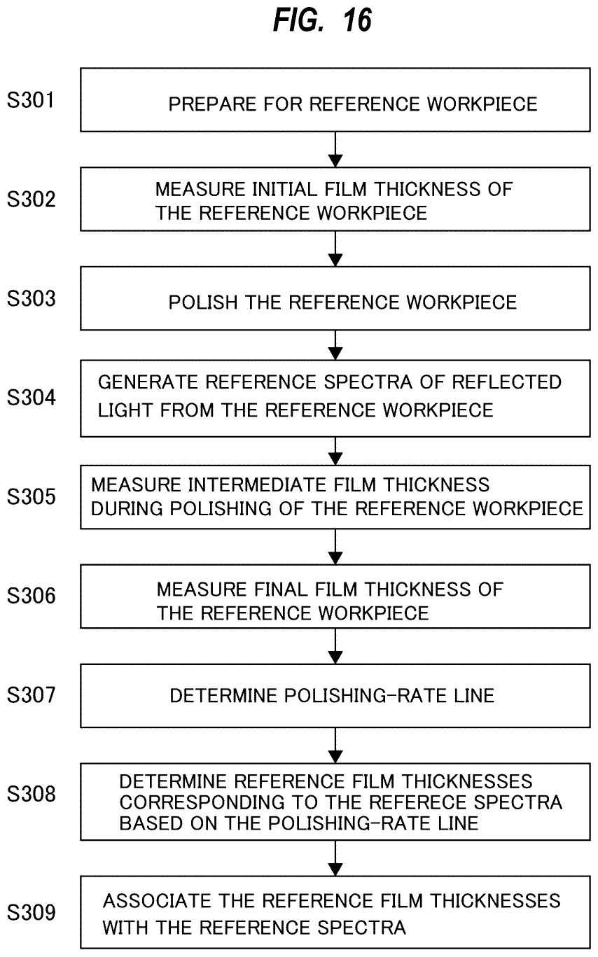

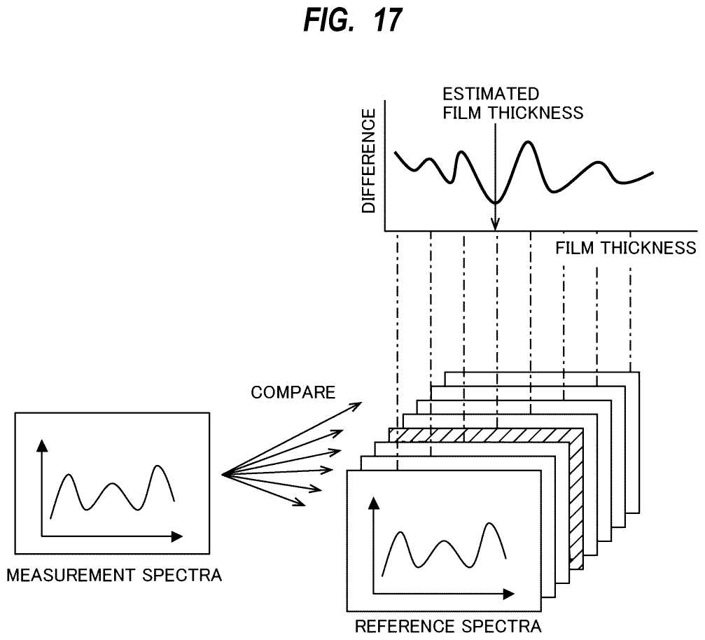

FIG. 16 is a flow chart illustrating one embodiment of the method of producing the reference-spectrum library.

Steps S301 to S304 are the same as the steps S101 to S104 shown in FIG. 11, and therefore duplicated descriptions will be omitted.

In step S305, the intermediate film thickness, which is a film thickness of the reference workpiece during polishing, is measured once or a plurality of times by the film-thickness measuring apparatus 101 or the optical film-thickness measuring device 20.

In step S306, after the reference workpiece is polished, the final film thickness, which is a film thickness of the polished reference workpiece, is measured by the film-thickness measuring apparatus 101.

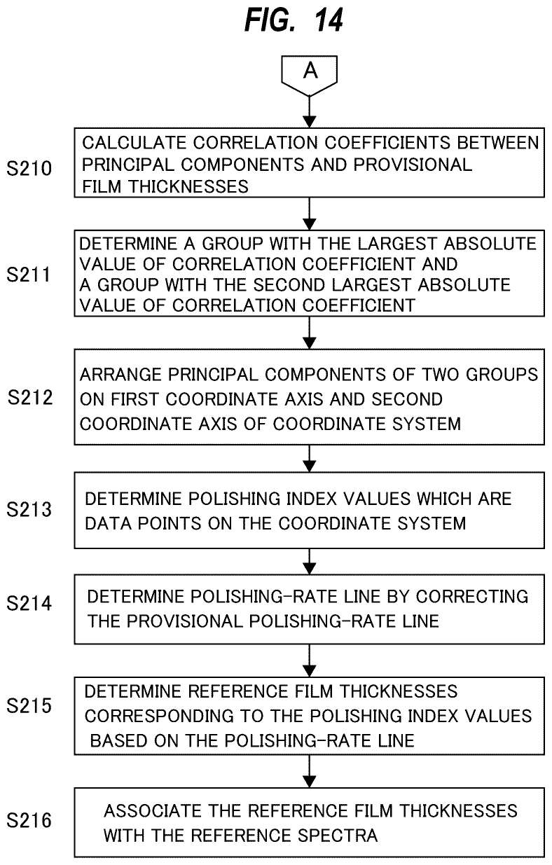

In step S307, the processing system 30 determines (creates) the polishing-rate line RRL indicating the relationship between the film thickness of the reference workpiece and the polishing time from the initial film thickness, the intermediate film thickness(es), and the final film thickness (see FIG. 14).

In step S308, the processing system 30 determines, based on the polishing-rate line RRL, the plurality of reference film thicknesses corresponding to the plurality of reference spectra.

In step S309, the processing system 30 associates the reference film thicknesses with the reference spectra, respectively. The reference spectra and the corresponding reference film thicknesses are added to the reference-spectrum library.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A method of producing a reference-spectrum library for use in estimation of a film thickness of a workpiece, comprising:
measuring an initial film thickness of a reference workpiece before being polished;
polishing the reference workpiece with a polishing apparatus;
generating a plurality of reference spectra of reflected light from the reference workpiece obtained at a plurality of polishing times during polishing of the reference workpiece;
measuring a final film thickness of the reference workpiece after polishing of the reference workpiece;
calculating a plurality of polishing index values indicative of a progress of polishing of the reference workpiece from the plurality of reference spectra;
determining a polishing-rate line indicative of a relationship between film thickness and polishing time of the reference workpiece from the initial film thickness, the polishing index values, and the final film thickness;
determining a plurality of reference film thicknesses corresponding to the plurality of polishing index values based on the polishing-rate line; and
producing the reference-spectrum library by associating the plurality of reference film thicknesses with the plurality of reference spectra, respectively.

2. The method of producing the reference-spectrum library according to claim 1, wherein calculating the plurality of polishing index values comprises:
calculating a plurality of amounts of change between the plurality of reference spectra, each amount of change being an amount of change between temporally adjacent two of the plurality of reference spectra; and
calculating the plurality of polishing index values by accumulating the plurality of amounts of change one by one arranged according to the polishing time of the reference workpiece.

3. The method of producing the reference-spectrum library according to claim 1, wherein determining the polishing-rate line comprises:
calculating a provisional polishing-rate line from the initial film thickness and the final film thickness, under an assumption that a polishing rate of the reference workpiece is constant; and
determining the polishing-rate line by correcting the provisional polishing-rate line based on changes in the plurality of polishing index values over polishing time.

4. The method of producing the reference-spectrum library according to claim 1, wherein calculating the plurality of polishing index values comprises:
calculating a plurality of provisional film thicknesses of the reference workpiece from the initial film thickness, the final film thickness, and the plurality of polishing times, under an assumption that a polishing rate of the reference workpiece is constant;
performing a principal component analysis on each of the plurality of reference spectra to obtain a plurality of principal components including a first principal component to a k-th principal component (k is a natural number equal to or greater than 2) for each of the reference spectra;
classifying the plurality of principal components obtained for the plurality of reference spectra into a plurality of groups of the first principal component to the k-th principal component;
determining a plurality of correlation coefficients corresponding to the plurality of groups by calculating the plurality of correlation coefficients between the plurality of principal components included in each of the plurality of groups and the plurality of provisional film thicknesses;
determining a first group having a largest absolute value of a correlation coefficient and a second group having a second largest absolute value of a correlation coefficient from among the plurality of correlation coefficients;
arranging the plurality of principal components included in the first group on a first coordinate axis of a coordinate system;
arranging the plurality of principal components included in the second group on a second coordinate axis of the coordinate system; and
determining the plurality of polishing index values which are a plurality of data points specified by the plurality of principal components on the first coordinate axis and the plurality of principal components on the second coordinate axis.

5. A method of producing a reference-spectrum library for use in estimation of a film thickness of a workpiece, comprising:
measuring an initial film thickness of a reference workpiece before being polished;
polishing the reference workpiece with a polishing apparatus;
generating a plurality of reference spectra of reflected light from the reference workpiece obtained at a plurality of polishing times during polishing of the reference workpiece;
measuring an intermediate film thickness of the reference workpiece at least once during polishing of the reference workpiece;
measuring a final film thickness of the reference workpiece after polishing of the reference workpiece;
determining a polishing-rate line indicating a relationship between film thickness and polishing time of the reference workpiece from the initial film thickness, the intermediate film thickness, and the final film thickness;
determining a plurality of reference film thicknesses at the plurality of polishing times from the polishing-rate line; and
producing the reference-spectrum library by associating the plurality of reference film thicknesses with the plurality of reference spectra, respectively.
